(19) United States
(12) Patent Application Publication
(10) Pub. No.: US 2020/0373091 A1
(43) Pub. Date: Nov. 26, 2020

(54) HIGH PERFORMANCE, HYSTERESIS-FREE, STABLE AND EFFICIENT PEROVSKITE SOLAR CELLS

(71) Applicants: Xiong Gong, Hudson, OH (US); Kai Wang, State Colledge, PA (US); Luyao Zheng, Akron, OH (US)

(72) Inventors: Xiong Gong, Hudson, OH (US); Kai Wang, State Colledge, PA (US); Luyao Zheng, Akron, OH (US)

(21) Appl. No.: 16/828,601

(22) Filed: Mar. 24, 2020

Related U.S. Application Data
(60) Provisional application No. 62/852,554, filed on May 24, 2019.
(60) Provisional application No. 62/864,727, filed on Jun. 21, 2019.

(51) Int. Cl. H01G 9/20; H01L 51/42

(52) U.S. Cl. CPC H01G 9/2009; H01L 51/424

(57) ABSTRACT

The present invention relates to a modified perovskite comprising a polymer that co-crystalizes with perovskite. In particular instances, the polymer is chosen from poly(ethylene oxide) (PEO) or polyethylenimine (PEI). A modified perovskite film includes an ionic salt; and a perovskite having the formula ABX₃, wherein counter anions of the ionic salt interact with A and counter cations interact with X, such that ion migration is suppressed.

### CROSS-REFERENCE TO RELATED APPLICATIONS

The present application claims the benefit of U.S. Provisional Patent Application No. 62/852,554, filed on May 24, 2019 and U.S. Provisional Patent Application No. 62/864,727, filed on Jun. 21, 2019, which are each incorporated herein by reference.

### STATEMENT REGARDING FEDERALLY SPONSORED RESEARCH OR DEVELOPMENT

This invention was made with government support under FA9550-15-1-0292 awarded by the Air Force Office of Scientific Research and EECS 1351785 awarded by the National Science Foundation. The government has certain rights in the invention.

### FIELD OF THE INVENTION

The present invention relates to perovskite materials utilized in solar cells. More particularly, the present invention relates to hybrid perovskite materials achieving hysteresis-free, stable, and efficient solution-processed perovskite solar cells (PSCs). Most particularly, the present invention relates to the utilization of polyethylene oxide (PEO) additives to anchor the counterions in the perovskite lattices to suppress the formation of point defect and the migration of ions, and to facilitate the crystal growth in a more thermodynamically preferred orientation.

### BACKGROUND OF THE INVENTION

Hybrid perovskite materials, because of their superior optoelectronic properties such as optimum band gap, good light absorption properties, long diffusion length, and cost-effective solution fabrication processes, have been used in the creation of high-performance and cost-effective solar cells. These materials are defined by a typical formula of ABX₃. Such materials have been known to have a power conversion efficiency of 23.7%. Single crystal and large grain-size polycrystalline hybrid lead halide perovskite (CH₃NH₃PBI₃) thin films have been reported as creating efficient PSCs, however, intrinsically inevitable electronic and structural disorders, ionic point defects, extended dislocations and grain boundaries of these thin films have restricted the PSC performance in terms of efficiency, stability, and hysteresis.

In CH₃NH₃PBI₃ thin films, the Schottky and Frenkel defects and the point vacancies of Pb²⁺, I⁻, and CH₃NH₃⁺ result in shallow donor or acceptor levels that lead to severe charge carrier recombination and, consequently, low short-circuit current (J_{SC}). Moreover, the tail states near the conduction band result in a broad distribution of the density of state, lowering the quasi Fermi level of electrons, and reducing the open-circuit voltage (V_{OC}). On the other hand, the first-principle calculation and various experimental studies utilizing impedance spectroscopy and field-switchable photovoltaic properties have demonstrated that the activation energies for ion migration in CH₃NH₃PBI₃ thin films are low (0.58 eV for I⁻, and 0.84 eV for CH₃NH₃⁺). Such moveable ions and their corresponding I⁻ and CH₃NH₃⁺ vacancies result in irreproducibility issues in the current-voltage (J-V) traces, also known as the photocurrent hysteresis, in PSCs. In addition, the site-vacancies can provide additional channels for moisture to be to reside in the hybrid perovskite materials, which would result in thermodynamically unstable materials. Furthermore, the point defects and the ion migration/drift induce local perturbation of non-stoichiometric compounds and create local crystal lattice collapse, with the final material having poor material stability.

The mechanism by which photocurrent hysteresis occurs is still under discussion, the main hypotheses include ferroelectricity, the trapping/de-trapping process, and ion migration. The polarization of the CH₃NH₃PBI₃ lattice gives rise to ferroelectricity, which affects the internal electric filed. However, the overall effect of ferroelectricity is not a big issue and its switching timescale exists around a nanosecond, which is too short for photocurrent hysteresis. As for the charge trapping/de-trapping process, it comes from intrinsic defects that solution-processed perovskite commonly possesses. These traps may locate near the band edge of CB/VB or at a deep energy level within the bandgap, relating to Shockley-Reed-Hall recombination. Based on spectroscopy characterizations, traps mainly exist at the interface or surface of perovskite crystals, in terms of vacancies, interstitials, and anti-sites.

On the other hand, due to the relatively low active energy and lattice disorder, I⁻ ions and CH₃NH₃⁺ ions are thought to migrate under an external electrical field. The first type of migration happens within neighboring lattices. When there exists a CH₃NH₃ vacancy (V_{MA}), I vacancy (V_{I}), and a Pb vacancy (V_{Pb}), ions will directly move to corresponding vacancies (MA⁺ moves to V_{MA}) under certain activity energies (Eₐ). Apart from near-by migration, lattice disorder by charge accumulation, impurity, and illumination can also induce cross-lattice migration. Furthermore, ions can also migrate by long-term disorder through grain boundaries (GB). At grain boundaries, small size perovskite grains can be easily shifted under an applied bias and a higher diffusivity giving ions faster movement opportunity inducing migrations. As a result of migration, ions will accumulate at the edge/interface area of perovskite, forming an extra electrical field. Depending on the direction of the internal bias, this extra electrical field can enhance build-in potential or suppress it. Those ions, accumulated at the edge/interface area, can facilitate charge extraction by transport layers, inducing different device performance. The disorder and ion migration are not good for device stability. Ion migration is expected to induce phase transition and lead local crystal lattice collapse. At the same time, the vacancy generation and migration in perovskite thin films provide the possibility for moisture entering the inner structure, which results in the degradation and depressed efficiency of PSCs.

Various polymers are incorporated into PSCs to boost device efficiencies. One study utilized low-molecular-weight organic gelators to facilitate the crystallization process to achieve higher quality perovskite active layers and thus obtained improved power conversion efficiency (PCE) of 14.5% while also enhancing the stability of the PSC. Another study employed an electron donor polymer as an interfacial layer to passivate the trap of perovskite materials. Yet another study employed insulating polymers as a scaffold layer infiltrated with perovskite resulting in efficient charge transport. Another study used poly(methyl methacrylate) as a template to foster an optimized crystallization of perovskite thin films and obtained an enhanced PCE for the formed PSCs. However, there has not been an in-depth understanding of the link between polymers and perovskite.

Therefore, there is the need in the art for a PSC that suppresses the formation of point defects and the migration of ions and the vacancies that result, while also facilitating the crystal growth in a more thermodynamically preferred orientation that sharpens the distribution of the density of states.

### SUMMARY OF THE INVENTION

In a first embodiment, the present invention provides a modified perovskite comprising a polymer and a perovskite wherein the polymer is co-crystallized with the perovskite.

In a second embodiment, the present invention provides a modified perovskite as in any embodiment above wherein the polymer is selected from the group consisting of poly(ethylene oxide) (PEO) and polyethylenimine (PEI).

In a third embodiment, the present invention provides a modified perovskite as in any embodiment above wherein the perovskire has the formula ABX₃ wherein A is selected from the group consisting of CH₃NH₃⁺ or NH₂CH═NH₂⁺, B is selected from the group consisting of Pb²⁺ or Sn²⁺, and X is a halide.

In a fourth embodiment, the present invention provides a modified perovskite as in any embodiment above, wherein X is selected from the group consisting of Cl⁻, Br⁻, or I⁻.

In a fifth embodiment, the present invention provides a modified perovskite as in any embodiment above, wherein A is CH₃NH₃⁺, B is Pb²⁺, and X is I⁻.

In a sixth embodiment, the present invention provides a modified perovskite as in any embodiment above, wherein PEO modifier anchors the CH₃NH₃⁺ at the A-site of the perovskite and the I⁻ at the X-site of the perovskite through the formation of hydrogen interactions between the PEO and the perovskite.

In a seventh embodiment, the present invention provides a perovskite solar cell comprising a light harvesting active layer comprising a modified perovskite comprising a polymer and a perovskite.

In an eighth embodiment, the present invention provides a perovskite solar cell as in the seventh embodiment, wherein the polymer is selected from the group consisting of poly(ethylene oxide) (PEO) and polyethylenimine (PEI).

In a ninth embodiment, the present invention provides a perovskite solar cell as in either of the seventh or eighth embodiments, wherein the perovskite has the formula ABX₃ wherein A is selected from the group consisting of CH₃NH₃⁺ or NH₂CH═NH₂⁺, B is selected from the group consisting of Pb²⁺ or Sn²⁺, and X is a halide.

In a tenth embodiment, the present invention provides a perovskite solar cell as in any of the seventh through ninth embodiments wherein X is selected from the group consisting of Cl⁻, Br⁻, or I⁻.

In an eleventh embodiment, the present invention provides a perovskite solar cell as in any of the seventh through tenth embodiments, wherein A is CH₃NH₃⁺, B is Pb²⁺, and X is I⁻.

In a twelfth embodiment, the present invention provides a perovskite solar cell as in any of the seventh through eleventh embodiments, further comprising an anode electrode selected from the group consisting of indium tin oxide (ITO).

In a thirteenth embodiment, the present invention provides a perovskite solar cell as in any of the seventh through twelfth embodiments, further comprising a hole extraction layer selected from the group consisting of nickel oxyhydroxide (NiOₓ) or poly(3,4-ethylenedioxythiophene) polystyrene sulfonate (PEDOT:PSS).

In a fourteenth embodiment, the present invention provides a perovskite solar cell as in any of the seventh through thirteenth embodiments, further comprising an electron extraction layer selected from the group consisting of phenyl-C61-butyric acid methyl ester (PC₆₁BM).

In a fifteenth embodiment, the present invention provides a perovskite solar cell as in any of the seven through fourteenth embodiments, further comprising a cathode electrode selected from the group consisting of aluminum.

In a sixteenth embodiment, the present invention provides a modified perovskite comprising: an ionic salt and a perovskite having the formula ABX₃, wherein counter anions of the ionic salt interact with A and counter cations interact with X, such that ion migration is suppressed.

In a seventeenth embodiment, the present invention provides a modified perovskite as in the sixteenth embodiment wherein the ionic salt is selected from the group consisting of tetrabutylammonium trifluoromethanesulfonate (TATS).

In an eighteenth embodiment, the present invention provides a modified perovskite as in either of the sixteenth or seventeenth embodiments wherein A is selected from the group consisting of CH₃NH₃⁺ or NH₂CH═NH₂⁺, B is selected from the group consisting of Pb²⁺ or Sn²⁺, and X is a halide.

In a nineteenth embodiment, the present invention provides a modified perovskite as in any of the sixteenth through eighteenth embodiments, wherein X is selected from the group consisting of Cl⁻, Br⁻, or I⁻.

In a twentieth embodiment, the present invention provides a modified perovskite as in any of the sixteenth through nineteenth embodiments, wherein A is CH₃NH₃⁺, B is Pb²+, and X is I⁻.

In a twenty-first embodiment, the present invention provides a modified perovskite as in any of the sixteenth through twentieth embodiments, wherein the TATS additive freezes movement of the I⁻ group of the perovskite while also suppressing migration of the CH₃NH₃⁺ group.

In a twenty-second embodiment, the present invention provides a perovskite solar cell comprising a light harvesting active layer comprising an ionic salt and a perovskite having the formula ABX₃, wherein counter anions of the ionic salt interact with A and counter cations interact with X, such that ion migration is suppressed.

In a twenty-third embodiment, the present invention provides a perovskite solar cell as in the twenty-second embodiment wherein the ionic salt is selected from the group consisting of tetrabutylammonium trifluoromethanesulfonate (TATS).

In a twenty-fourth embodiment, the present invention provides a perovskite solar cell as in either the twenty-second or twenty-third embodiments wherein A is selected from the group consisting of CH₃NH₃⁺ or NH₂CH═NH₂⁺, B is selected from the group consisting of Pb²⁺ r Sn²⁺, and X is a halide.

In a twenty-fifth embodiment, the present invention provides a perovskite solar cell as in any of the twenty-second through twenty-fourth embodiments, wherein X is selected from the group consisting of Cl⁻, Br⁻, or I⁻.

In a twenty-sixth embodiment, the present invention provides a perovskite solar cell as in any of the twenty-second through twenty-fifth embodiments, wherein A is CH₃NH₃⁺, B is Pb²⁺, and X is I⁻.

In a twenty-seventh embodiment, the present invention provides a perovskite solar cell as in any of the twenty-second through twenty-sixth embodiments, further comprising an anode electrode selected from the group consisting of indium tin oxide (ITO)

In a twenty-eighth embodiment, the present invention provides a perovskite solar cell as in any of the twenty-second through twenty-seventh embodiments, further comprising a hole extraction layer selected from the group consisting of nickel oxyhydroxide (NiOₓ) or poly(3,4-ethylenedioxythiophene) polystyrene sulfonate (PEDOT:PSS).

In a twenty-ninth embodiment, the present invention provides a perovskite solar cell as in any of the twenty-second through twenty-eighth embodiments, further comprising an electron extraction layer selected from the group consisting of phenyl-C61-butyric acid methyl ester (PC₆₁BM).

In a thirtieth embodiment, the present invention provides a perovskite solar cell as in any of the twenty-second through twenty-ninth embodiments, further comprising a cathode electrode selected from the group consisting of aluminum.

### DETAILED DESCRIPTION OF ILLUSTRATIVE EMBODIMENTS

An embodiment of the present invention is based on the use of making modified perovskite films co-crystallized with polymers through hydrogen bonding. In one or more embodiments of the present invention, virtually any perovskite may be used. In some embodiments, the perovskite is known by the formula ABX₃, in some instances having a similar crystal structure to CaTiO₃. In one or more embodiments of the present invention, the polymer utilized can be any polymer that co-crystallizes with the selected perovskite. In one or more embodiments of the present invention, the modified perovskite films co-crystallized with polymers can be used to create hysteresis-free, stable and efficient perovskite photovoltaics.

An embodiment of the present invention is based, at least in part, on compositions useful in solar cells. Specifically, an embodiment of the present invention relates to the utilization of poly(ethylene oxide) (PEO) as an additive to anchor CH₃NH₃⁺ or NH2CH═NH2⁺ at the A site and I— at the X-site of perovskite through formation of hydrogen interactions between PEO and CH₃NH₃PBI₃, which suppresses the formation of point defect and the migration of ions/vacancy while also facilitating the crystal growth in a more thermodynamically preferred orientation, which leads to a sharp distribution of the density of states. As a result, un-encapsulated PSCs including a PEO—CH₃NH₃PBI₃ thin film and operated in air with 50% humidity, exhibit stable power conversion efficiency (PCE) of 19.01% with hysteresis-free characteristics and 504 hours half shelf-life time as compared with that of PSCs utilizing pristine CH₃NH₃PBI₃ thin films, which, for comparison, exhibit unstable PCEs (ranging from 11.80% to 16.14%), with dramatically high hysteresis (ranging from 0.025 to 0.045) and 69 hours half shelf-life time.

In principal, there are two chemical interactions between the PEO additives and CH₃NH₃PBI₃. Specifically, the oxygen in the backbone of the PEO can form a hydrogen interaction of O . . . H—NH₂CH₃⁺ with CH₃NH₃⁺ at the crystal-A-site, and the hydroxyl group at the end of PEO can form a hydrogen interaction of —OH . . . I— with the I— at the crystal-X-site in the PBI6 octahedra framework. Fourier transform infrared (FT-IR) spectra were taken of PEO, CH₃NH₃PBI₃ and PEO—CH₃NH₃PBI₃ thin films and showed that the PEO—CH₃NH₃PBI₃ thin films, similar to that of PEO, exhibited a wide ‘O—H’ stretching vibration peak, which is originated from the inter- and intra-molecular hydrogen bonds. Moreover, it was found that CH₃NH₃⁺ showed a ‘N—H’ stretching peak with a half width at half maximum (HWHM) of 185 cm−1 in pristine CH₃NH₃PBI₃ thin films, whereas, a 302 cm−1 HWHM was observed with the PEO—CH₃NH₃PBI₃ thin films. These results demonstrated that the backbone of PEO formed a hydrogen interaction of O . . . H—NH₂CH₃⁺ with CH₃NH₃⁺ at the crystal-A-site. However, the hydrogen interaction of ‘OH . . . I’ was too weak to be detected in any shift or splitting of the infrared frequency of the stretching modes.

According to one embodiment of the present invention, in order to prepare a PEO modified perovskite thin film, the following steps are taken. First, a precursor solution utilizing either Pb²⁺ or Sn²⁺ bonded to a halide should be prepared. For example, Pb²⁺ bonded with I— can be selected to prepare a precursor solution of PbI₂, PbI₂ is added into a solvent solution, such as for example, a combination of DMF and DMSO. This solution can then be mixed with a PEO solution. The Mw of the PEO solution can range from 500 Da to 4500 Da, with anything over 4500 Da being too difficult to dissolve in the solvent. Furthermore, the concentration of the PEO solution can range from 1% to 10%. To complete the first step, the PBI₂ layer mixed with the PEO additive is deposited on to a substrate by spin-casting.

The next step in preparing a PEO modified perovskite thin film is to deposit a layer utilizing either CH₃NH₃⁺ or NH₂CH═NH₂⁺. For example, methyl ammonium iodide (MAI) is selected to deposit a CH₃NH₃⁺ layer. The MAI layer can be spun cast on the top of the PBI₂ mixed with the PEO additive layer from a MAI precursor solution. Once this layer is deposited, the combined layers can then be thermally annealed at about 100° C. for about two hours to create the final perovskite thin film.

Once the PEO modified perovskite thin film has been created, it can be utilized to create a perovskite solar cell (PSC). In one embodiment of the present invention, in order to prepare the PSC, the following steps may be taken. First, a material to create an anode electrode needs to be selected from the group consisting of indium tin oxide (ITO). Once selected, the material to create the anode electrode should be cleaned by detergent, deionized water, acetone, and then isopropanol sequentially. Once cleaned, the anode electrode can be dried in an oven at about 100° C. overnight. Once dried, the anode electrode can be treated with UV-ozone for about 40 minutes under an ambient atmosphere. The next step is to select a material to create a hole extraction layer selected from the group consisting of nickel oxyhydroxide (NiOₓ) or poly(3,4-ethylenedioxythiophene) polystyrene sulfonate (PEDOT:PSS). Once selected, the material to create the hole extraction layer can be spun cast on top of the anode electrode utilizing a hole extraction layer precursor solution to create about a 40 nm thick film layer.

The next step is to take the PEO modified perovskite thin film and deposit it on top of the hole extraction layer utilizing a two-step method to create a light harvesting active layer. The next step is to select a material to create an electron extraction layer selected from the group consisting of phenyl-C61-butyric acid methyl ester (PC₆₁BM). Once selected, the material selected to create the electron extraction layer is spun cast onto the PEO modified perovskite thin film layer. The final step is to select a material to create a cathode electrode selected from the group consisting of aluminum. Once selected, the material selected to create the cathode electrode is deposited by a shadow mask in a vacuum onto the electron extraction layer.

Liquid-state ¹HNMR spectra were also taken for deuterated PEO, CH₃NH₃PBI₃, and PEO—CH₃NH₃PBI₃ dimethyl sulfoxide (DMSO) solutions. For the PEO solution, double methylene groups linked with oxygen in the main-chain (—(OCH₂CH₂)ₙ)—) was characterized by a peak at δ=3.51 ppm and the hydroxyl group (—OH) at the end of chain was characterized by a peak at δ=4.59 ppm. With the CH₃NH₃PBI₃ solution, only one peak was located at δ=7.42 ppm, which corresponds to CH₃NH₃⁺ group. With the PEO—CH₃NH₃PBI₃ solution, the protons from the methylene group in the PEO main-chain show an up-field shift of Δδ of about 0.2 ppm. Due to the formation of the hydrogen bond between CH₃NH₃⁺ and the O in the PEO chain, the influence of O on the protons of methylene are weak. But the protons from the methyl group at the end of the PEO chain show a large up-field shift of Δδ of about −1.4 ppm, which is ascribed to the ‘OH . . . I’ interaction. Similarly, the resonance signals arising from the −NH3+ protons of PEO—CH₃NH₃PBI₃ also undergo a significant up-field shift of Δδ of about −0.3 ppm, which proves the ‘O . . . H—NH₂CH₃⁺’ hydrogen-bonding interaction. Thus, these results demonstrate the confirmation of the intramolecular interaction of “O . . . H—NH₂CH₃⁺’ and ‘—OH . . . I—’ between PEO and CH₃NH₃PBI₃. Such intramolecular interaction also suggests that the activation energies for I— and CH₂NH₃⁺ migration in PEO—CH₃NH₃PBI₃ thin films are higher than those in pristine CH₃NH₃PBI₃ thin films.

X-ray diffraction (XRD) spectroscopy was also employed to scrutinize the influence of PEO on the perovskite crystal structure. With a PEO—CH₃NH₃PBI₃ powder, the major phase is a tetragonal structure with minor additional scattering peaks. These new scattering peaks are most likely originating from the hydrogen interaction between PEO and neighboring CH₃NH₃PBI₃. An in-situ grazing-incidence wide-angle x-ray scattering (GIWAXS) study was further undertaken to investigate the influence of PEO on the orientation of perovskite polycrystals. As the annealing temperature was increased, the scattering intensities of the perovskite scattering feature for both PEO—CH₃NH₃PBI₃ and CH₃NH₃PBI₃ thin films are increased. Moreover, even at high temperatures of 120° C., some scattering rings induced by the ‘—OH . . . I—’ interaction still remained, which indicates that the PEO—CH₃NH₃PBI₃ thin film possesses a relatively high thermal stability compared to that of a pristine CH₃NH₃PBI₃ thin film. However, the number of peaks induced by the ‘—OH . . . I—’ interaction in the PEO—CH₃NH₃PBI₃ thin film is reduced, which is probably due to broken hydrogen bonds at elevated temperatures.

Top-view scanning electron microscopy (SEM) images of a pristine CH₃NH₃PBI₃ thin film and a PEO—CH₃NH₃PBI₃ thin film where also taken, with the molecular weight of the PEO in the PEO—CH₃NH₃PBI₃ thin film being varied. The pristine CH₃NH₃PBI₃ thin film possessed many defects and voids. But the PEO—CH₃NH₃PBI₃ thin films exhibited a wide-range of morphological and topological evolutions from “crystal dots” (with PEO of Mw of 500 Da), “crystal fibers” (with PEO of Mw of 1000 Da), and “crystal bulk” (with PEO of Mw of 4500 Da). It was clear that the pin-holes and grain boundaries were dramatically reduced with increased Mw of PEO. Such a strong effect from the increased Mw of the PEO on the thin film morphology is likely attributed to the slow crystal growth process induced by the hydrogen interaction in the PEO—CH₃NH₃PBI₃ thin films. Since the crystal growth is a diffusion-control process, as Mw increases, more ‘O . . . H—NH₂CH₃⁺’ hydrogen interactions are introduced, which forms intermediate adducts, reducing the crystal growth rate and consequently resulting in larger crystal domains. Such film morphological change is further evidenced by the scattering characterizations, where wider characteristics peaks for the PEO—CH₃NH₃PBI₃ thin films with high Mw demonstrate that a larger amount of hydrogen interactions have been introduced into the lattice, thus resulting in flattered scattering peaks. With these studies, it was noted that when the Mw of PEO exceeded 4500 Da, resulted in inferior film morphology. Thus, the optimal thin film morphology with the largest crystal domain and minimized boundaries was observed for the PEO—CH3NH3PBI3 then films wherein the Mw of the PEO is 4,500 Da.

A contact angle with water measurement study was carried out to further verify the topological evolution of these thin films. The loosely packed porous pristine CH₃NH₃PBI₃ showed a small contact angle of 39.5°, while the contact angles were enlarged in different scales for the PEO—CH₃NH₃PBI₃ thin films, in which PEO had different Mw. The interpenetrating “crystal fiber” topology showed a maximum contact angle of 110.9°. Apart from the unique surficial features, such large contact angles are most likely due to the PEO anchoring effect, which induces reorientation of the CH₃NH₃⁺ at the surface and enlarges the steric hindrance for moisture attack. Such hydrophobic characteristics will enhance the chemical stability of the PEO—CH₃NH₃PBI₃ thin films.

Top-view SEM images of the PEO—CH₃NH₃PBI₃ thin films, where the Mw of PEO is 4500 Da and the concentrations of PEO ranged from 1%, 3%, 5%, and 10% were taken. It was found that the crystalline grain sizes increased from about 300 nm at 1%, about 700 nm at 3%, about 1500 nm at 5%, and about 1250 nm at 10%. A hollow feature was observed for the PEO—CH₃NH₃PBI₃ thin where the concentration of PEO was at 10%. This feature is ascribed to the burned residual PEO by the high energy electron beam. The existence of the residual PEO is clearly shown in the PEO—CH₃NH₃PBI₃ thin films the PEO concentration reached 10%. Thus, a larger grain size and smaller grain boundaries were observed for the PEO—CH₃NH₃PBI₃ thin film, when the Mw of PEO is 4500 Da and the concentration of PEO is 5%. This range of Mw and concentration is expected to deliver optimal electronic properties, resulting in superior photovoltaic properties.

The photovoltaic properties of the PEO—CH₃NH₃PBI₃ thin films were investigated through the evaluation of device performance of PSCs with a planar heterojunction device structure of ITO/NiOₓ/CH₃NH₃PbI₃(or PEO—CH₃NH₃PBI₃)/PC₆₁BM/Al, where ITO is indium tin oxide and acts as an anode electrode; NiOₓ is used as the hole extraction layer; the CH₃NH₃PBI₃ or the PEO—CH₃NH₃PBI₃ acts as a light harvesting active layer; PC₆₁BM is phenyl-C61-butyric acid methyl ester and is used is the electron extraction layer; and Al is aluminum and acts as the cathode electrode.

Under one-sun illumination with the light intensity 100 mW/cm2, under the scan rate of 0.10 V/s, and a reverse scan direction, the PSCs utilizing pristine CH₃NH₃PBI₃ thin film exhibit a J_{SC} of 21.08 mA/cm², a V_{OC} of 1.05 V and a fill factor (FF) of 74.7%, with a corresponding PCE of 16.57%. Whereas the PSCs by the PEO—CH3NH3PBI3 thin films, where Mw of PEO is 4500 Da and the concentration of PEO is 5%, exhibits a J_{SC} of 22.38 mA/cm², a V_{OC} of 1.10 V and a FF of 77.8%, with a corresponding PCE of 19.03%, which presents a 35% enhancement compared to that by pristine CH₃NH₃PBI₃ thin films.

PSCs utilizing the PEO—CH₃NH₃PBI₃ thin films have nearly identical J-V curves, but the PSCs utilizing pristine CH₃NH₃PBI₃ thin films have significantly different J-V curves. The difference in J-V curves under different scan directions indicates that PSCs possess photocurrent hysteresis. Photocurrent hysteresis is described as a dimensional hysteric index (HI). High HI values ranging from 0.025 to 0.045 and corresponding PCE values ranging from 11.80% to 16.14 were observed for PSCs utilizing pristine CH₃NH₃PBI₃ thin films, whereas an HI of 0.0001, a negligible value, and a stable PCE value of 19.01±0.06% was observed for the PSCs utilizing the PEO—CH₃NH₃PBI₃ thin films. These results demonstrate that the PSCs utilizing the PEO—CH₃NH₃PBI₃ thin films possess enhanced PCEs and hysteresis-free characteristics.

Charge extraction efficiency was investigated by transient photocurrent (TPC) measurements. Charge carrier extraction lifetimes were estimated through extrapolating the linear regime of TPC curves. The PSCs fabricated by the PEO—CH₃NH₃PBI₃ thin film exhibited a shorter carrier extraction time of 78 ns as compared to 110 ns for the PSCs fabricated by pristine CH₃NH₃PBI₃ thin films, demonstrating that the charge extraction is more efficient, resulting in enhanced PCEs. All these results demonstrate that the PSCs by the PEO—CH₃NH₃PBI₃ thin film exhibit enhanced PCEs.

To further understand boosted device performance, the point defects within the crystal lattice by counter ions and the structural in-continuity with less boundaries and pin-hole impurities by large crystal domains in the PEO—CH₃NH₃PBI₃ thin films are investigated by distribution of the density of state (DOS). For a solar cell operated at V_{OC}, no charge is being collected at the electrodes. As a result, a change of chemical capacitance results from a variation of the Fermi energy due to a variation of the charge carrier density from the photo-generated charge carriers in the photoactive layer. Thus, the differential of the electronic states of different photoactive layers can be used to verify the DOS distributions through the Gaussian approximation. Therefore, the DOS representatively reflects the electrical fact of photoactive layer. A smaller Gaussian approximation of 121 meV was observed from the PSCs utilizing PEO—CH₃NH₃PBI₃ thin films as compared with 231 meV from the PSCs utilizing CH₃NH₃PBI₃ thin films, which demonstrates that PEO—CH₃NH₃PBI₃ thin films exhibit a narrower DOS distribution. As a result, PSCs utilizing PEO—CH₃NH₃PBI₃ thin films exhibit enhanced J_{SC} and enlarged FF, consequently resulting in a boosted PCE.

Recombination resistance (R_{rec}), which is related to the recombination current density j_{rec}, is extracted from the impedance measurement at low frequency, and was recorded for PEO—CH₃NH₃PBI₃ and CH₃NH₃PBI₃ thin films. The R_{rec} is related to V_{OC} in terms of the recombination order parameter. The PSCs utilizing PEO—CH₃NH₃PBI₃ thin films exhibited a recombination order parameter of 1.96, which is in good agreement with a theoretical value of 2, which indicates a second order recombination mechanism is taking place in the cell. In comparison, PSCs utilizing pristine CH₃NH₃PBI₃ thin films exhibited a recombination order parameter of 1.38, indicating the shallow trap-induced first order recombination mechanism taking place in the cell. Therefore, PSCs utilizing PEO—CH₃NH₃PBI₃ thin films possess better device performance as compared to PSCs utilizing pristine CH₃NH₃PBI₃ thin films.

A longer carrier lifetime over a wide range of photovoltages was observed with the PSCs utilizing PEO—CH₃NH₃PBI₃ thin films compared to PSCs utilizing CH₃NH₃PBI₃ thin films. Specifically, under one sun white light illumination, the recombination lifetime of the PSCs utilizing PEO—CH₃NH₃PBI₃ thin films was 4.2 μs, which is longer than that of PSCs utilizing CH₃NH₃PBI₃ thin films, which had a recombination lifetime of 1.5 μs. Such elongated charge carrier recombination lifetime is attributed to the PEO anchoring effect, which results in minimized defects and trap states, where there is less chance for charge recombination during the transport. As compared with pristine CH₃NH₃PBI₃ thin films, a longer charge carrier lifetime observed from PSCs utilizing PEO—CH₃NH₃PBI₃ thin films indicates that less charge recombination occurred, and thus, PSCs utilizing PEO—CH₃NH₃PBI₃ thin films possess higher J_{SC}.

The shelf-stability of PSCs as a function of aging time was also studied by testing unencapsulated PSCs at room temperature in an ambient condition with 50% relative humidity. The PSCs utilizing pristine CH₃NH₃PBI₃ thin films exhibited a rapid decrease in J_{SC}, V_{OC}, FF, and PCE during the aging process, with a half shelf-life time of about 69 hours; whereas the PSCs utilizing the PEO—CH₃NH₃PBI₃ thin films exhibited a dramatically alleviate decay rate and a significantly extended half shelf-life time of 504 hours.

To understand the improved stability of PSCs, the UV-vis absorption spectra of pristine CH₃NH₃PBI₃ thin films and PEO—CH₃NH₃PBI₃ thin films, at an ambient condition with 50% relative humidity at room temperature were studied. It was found that the absorption edge of pristine CH₃NH₃PBI₃ thin films blue shifted after 6 days, and the intensity of absorption in the visible region was gradually reduced, implying that pristine CH₃NH₃PBI₃ thin films were being degraded. Moreover, after 20 days, the absorption edge reduced to about 500 nm and the film color became yellow, which indicated that only PbI2 was left and that the CH₃NH₃⁺ was totally drained. However, for the PEO—CH₃NH₃PBI₃ thin film, the absorption spectrum of the PEO—CH₃NH₃PBI₃ thin films is almost identical, regardless of the intensity and absorption edge after 40 days, and while the absorption intensity started to reduce after 45 days, the absorption edge still remained at 780 nm. All these results demonstrated that a much lower degree of decompensation happens with the PEO—CH₃NH₃PBI₃ thin films even if the PEO—CH₃NH₃PBI₃ thin films is under ambient air with 50% relative humidity at room temperature. Further, these results demonstrated that the hydrogen interactions probably raise up the activation energy height for the PEO—CH₃NH₃PBI₃ thin films when reacted with moisture, resulting in enhanced stability in the PSCs utilizing PEO—CH₃NH₃PBI₃ thin films. Additionally, the topological features of larger contact angles with moisture and less pin-holes for moisture diffusion within the PEO—CH₃NH₃PBI₃ thin films offers stronger resistance to moisture as well. Consequently, boosted stability is realized in PSCs utilizing PEO—CH₃NH₃PBI₃ thin films.

Statistic histograms gathered from over 100 identical devices and their corresponding Gaussian fitting for the PCEs of PSCs were taken. The PSCs fabricated utilizing CH₃NH₃PBI₃ thin films exhibited a severe deviation, ranging from 13.51% to 18.46%. In comparison, the PSCs fabricated with PEO—CH₃NH₃PBI₃ thin films exhibited a smaller standard deviation, with a PCE of 18.86±0.19%. Accordingly, the significantly narrowed confidence interval of 1.01% for PCEs and a confidence level of 95% indicates that the PSCs fabricated with PEO—CH₃NH₃PBI₃ thin films possess a high level of reproducibility.

Other embodiments of the present invention are based, in least in part, on compositions useful in solar cells. Specifically, an embodiment of the present invention relates to the utilization of linear polyethylenimine (PEI) with perovskite solar cells (PSCs) in order to address photocurrent hysteresis. The PEI freezes counter ions through forming hydrogen bonds between imine groups from the PEI and the amine groups from the CH₃NH₃PBI₃ perovskite. Hydrogen bounding intermediates were found to spontaneously form in perovskite precursor solutions and were found to slow down the crystallization process under thermal annealing. The controlled crystallization and compact grain boundaries (GBs) resulted in less lattice disorder and less channels for ion migration. Therefore, significantly restricted photocurrent hysteresis was observed in PEI—CH₃NH₃PBI₃ perovskite solar cells. A 20% enhancement in power conversion efficiencies (PCE) was also demonstrated.

The polymeric additive PEI was found to act as a crosslink agent due to the formation of hydrogen bonds between the imine group of the PEI and the CH₃NH₃⁺ group of the CH₃NH₃PBI₃, hence, movement of CH₃NH₃⁺ can be restricted, indicating less hysteresis behavior. By incorporating certain specific polymeric additives, a universal rule of hydrogen bounding effect in the perovskite active layer is expected. As a result, a 20% enhancement in device performance can be achieved with the utilization of a PEI modified CH₃NH₃PBI₃ PSC where photocurrent hysteresis was strongly suppressed, and device stability was enhanced to some degree as compared to a pristine CH₃NH₃PBI₃ PSC.

In one embodiment of the present invention, in order to create a PEI modified perovskite thin film; the following steps are taken. First, a precursor solution utilizing either Pb²⁺ or Sn²⁺ bonded to a halide is prepared. For example, Pb²⁺ bonded with I⁻ can be selected to prepare a precursor solution of PbI₂. PbI₂ is added into a solvent solution, such as for example, a combination of DMF and DMSO. Next, a solution utilizing either CH₃NH₃⁺ or NH₂CH═NH₂⁺ is to be prepared. For example, methyl ammonium iodide (MAI) is selected to mix in CH₃NH₃⁺. These two solutions are created to make a perovskite precursor solution. These two solutions are combined in an equal molar ratio. The perovskite precursor solution is then mixed with a PEI solution dissolved in a solvent solution, such as for example, ethanol, at a concentration of about 2.5 mg mL⁻¹. When the PEI modified perovskite thin films are created, they are made in multiple concentrations of perovskite:PEI of 400:5, 400:10, 400:20, and 400:30.

Once the PEI modified thin film has been created, it can be utilized to create a perovskite solar cell (PSC). In one embodiment of the present invention, in order to prepare the PSC, the following steps are taken. First, a material to create an anode electrode needs to be selected from the group consisting of indium tin oxide (ITO). Once selected, the anode electrode should be treated with UV-ozone for about 40 minutes under an ambient atmosphere. The next step is to select a material to create a hole extraction layer selected from the group consisting of nickel oxyhydroxide (NiOₓ) or poly(3,4-ethylenedioxythiophene) polystyrene sulfonate (PEDOT:PSS). Once selected, the material to create the hole extraction layer is spun cast on top of the anode electrode utilizing a hole extraction layer precursor solution to create about a 40 nm thick film layer. Once the hole extraction layer has been spun cast onto the anode electrode, it is thermally annealed for about 10 minutes at about 150° C. Then, the device is placed into a glovebox with an N₂ atmosphere.

The next step is to take the PEI modified perovskite thin film and deposit it on top of the hole extraction layer utilizing a one-step method using spin-coating. This step will create a light harvesting active layer. Then, an anti-solvent, such as toluene, is dripped for about 15-10 seconds at the conclusion of the spin-coating. A 300 nm PEI modified perovskite layer is then created after 10 minutes of thermal annealing at 100° C. The next step is to let the device cool down to room temperature and then a material is selected to create an electron extraction layer selected from the group consisting of phenyl-C61-butyric acid methyl ester (PC₆₁BM). Once selected, the material selected to create the electron extraction layer is spun cast onto the PEI modified thin film layer. The final step is to select a material to create a cathode electrode selected from the group consisting of aluminum. Once selected, the material selected to create the cathode electrode is deposited by a shadow mask in a vacuum onto the electron extraction layer.

The top-view film morphology of both pristine CH₃NH₃PBI₃ and PEI—CH₃NH₃PBI₃ were observed through scanning electron microscope (SEM) measurements. From the SEM images, it was obvious that PEI—CH₃NH₃PBI₃ had a larger crystal size (300 nm) as compared to pristine CH₃NH₃PBI₃. Less grain boundaries and pin-holes could be addressed in PEI—CH₃NH₃PBI₃, which was also better than pristine CH₃NH₃PBI₃ thin films. The large grain size and more homogenous film morphology indicated better exciton generation and the corresponding charge carrier transport process. Therefore, a higher J_{SC} and efficiency is to be expected from PEI—CH₃NH₃PBI₃ solar cells as compared to solar cells utilizing pristine CH₃NH₃PBI₃.

To characterize the hydrogen bonds between CH₃NH₃⁺ and PEI, solution NMR was performed on just PEI, pristine CH₃NH₃PBI₃, and PEI—CH₃NH₃PBI₃ systems in deuterated DMSO solvent and the results were compared. The NMR images gave proof of hydrogen bonds in the PEI/perovskite system as a PEI—CH₃NH₃⁺ I⁻ intermediate. During the formation of perovskite, the MA linked with PEI had a higher barrier and slowed down the crystallization process, so that a larger crystal size could be achieved in a PEI—CH₃NH₃PBI₃ system. PEI has a long soft chain and could form multi-hydrogen bonds with different MA+ ions, and the ions could be involved in the same or different perovskite crystals. When different perovskite crystals are linked by the same PEI chain, a “cross-linked perovskite” could be formed. To take one step further, PEI had not reaction with the formation of perovskite, so that it could only exist at grain boundaries and the surface of perovskite thin films. Apart from acting as a cross-linking agent, PEI could also work as a “polymer scaffold” to further modify film morphology of perovskite.

The performance of PSCs with different concentrations of PEI were also studied. Compared with a control device made from pristine CH₃NH₃PBI₃, a great enhancement could be seen in PSCs made with 400:10 and 400:20 (CH₃NH₃PBI₃:PEI) concentrations. A J_{SC} of 22.5 mA/cm² and a V_{OC} of 0.84 V boosted PSC device performance to 14%, a 20% enhancement as compared to pristine CH₃NH₃PBI₃ solar cell. With increasing PEI concentrations, the enhancement in both J_{SC} and V_{OC} could be observed, while the photocurrent decreased in the highest concentration (400:40). Higher concentrations of PEI enlarged series resistance due to its insulating properties, such that the photocurrent would be sacrificed. The PEI—CH₃NH₃PBI₃ is considered a narrow-density-of-state light harvesting material, so that the device had a higher V_{OC}. V_{OC} also has a connection to recombination, and under the same illumination intensity, both films exhibit identical light absorption spectra. Hence, the same quantity of photo-generated charge carriers is presented in the initial stage for both films. Stronger deep-level trap-assisted recombination will consume more excited electrons and will turn out less excited electrons at the high energy conduction band (CB) edge. Therefore, PEI—CH₃NH₃PBI₃ active layers will have a smaller recombination rate and a smaller recombination rate indicates more electrons reaching and staying in CB and incorporating with a sharp DOS.

Photocurrent hysteresis behaviors were also studied for PEI modified PSCs with different concentrations of the PEI additive. Under different scan directions (scan rate 2000 mV/s), PEI—CH₃NH₃PBI₃ PSCs exhibited reduced hysteresis behaviors with increasing PEI concentrations up to 400:20. These results matched with previous J-V characterizations studies that showed that device performance increased with PEI concentrations of 400:20 as compared to pristine CH₃NH₃PBI₃. The enhanced device performance is believed to result from less hysteresis due to less defects and recombination. Compared with pristine PSCs, PEI modified PSCs exhibited more significant enhancement to the CH₃NH₃PBI₃ active layer, supported by impressive device performance and strongly reduced photocurrent hysteresis.

Both the reduced hysteresis behavior and the frozen ion migration indicate a lower trap density with less recombination in the perovskite active layer. In order to further investigate the electronic properties, the hole/electron trap density was calculated by using the trap-filled limited law (TFL) on a single carrier device. With a single carrier device current-voltage measurement, only one kind of charge carrier (hole or electron) can be transported and collected by the electrode. When applying a small voltage, devices obey ohm's law, presenting a first order relationship. With increasing voltage, the injection of electrons will fill inner traps and at certain voltage (trap-filled limited voltage V_{TFL}) all traps will be filled, defined as the trap-filled limited law (TFL). Then, current-voltage characterization will reach the space-charge-limited-current region (SCLC), which gives a second order relationship. Therefore, one can measure V_{TFL} from a single carrier device and use that value to calculate the corresponding trap density. For an electron only device, an ITO/Al (10 nm)/Perovskite/PC₆₁BM/Al (100 nm) single carrier device was fabricated and for a hole only device, an ITO/PEDOT:PSS/Perovskite/MoO3 (15 nm)/Ag (120 nm) single carrier structure was fabricated. Compared with pristine perovskite solar cells, PEI modified PSCs (400:20) exhibited a much lower electron/hole trap density. Less trap density indicates a more uniform perovskite active layer (less lattice disorder) and both recombination possibility as well as disordered ions were smaller than compared to pristine PSCs. Therefore, a better device performance with less hysteresis was observed for PEI—CH₃NH₃PBI₃ PSCs.

Single carrier device J-V characterization demonstrated less trap density in PEI-modified PSCs; hence it was necessary to investigate the corresponding trap-assisted recombination. Light intensity dependent J-V characterization was used to study the recombination. By measuring the J-V curve under different light intensities (from 100 mW/cm² to 10.5 mW/cm²), a linear relationship can be found between V_{OC} and the logarithm of the light intensity. The results showed that PEI—CH₃NH₃PBI₃ PSCs has a smaller recombination index than pristine PSCs. Less trap density and recombination guaranteed more effective charge carrier transport, so that photocurrent could be higher. Furthermore, less lattice disorder and ion migration origin from more uniform perovskite crystals paved the way for a reduced hysteresis behavior in PEI—CH₃NH₃PBI₃ PSCs.

To further confirm the enhancement to the PSCs provided by the PEI additive, IS and TPC measurements were used to address charge carrier extraction and transport properties. Charge carrier transport resistance (R_{CT}) and recombination resistance (R_{rec}) could be estimated from an IS Nyquist plot measured under one-sun light and dark conditions, applying V_{OC} bias. The IS of PSCs fabricated with or without PEI additives were taken. From an equivalent circuit, R_{CT} and R_{rec} could be calculated as the resistance between two intersection points of the Nyquist plot and the Z′ axis. Pristine PSCs had an R_{CT} of 95Ω while PEI-modified PSCs has a smaller R_{CT} of 73Ω. A smaller R_{CT} indicates a more effective charge carrier transport process, therefore, a higher photocurrent could be detected in the PEI-modified PSCs. The R_{rec} of pristine PSCs was calculated as 4750Ω while the PEI-modified PSCs had a R_{rec} of 6100Ω, indicating less recombination behaviors in the PEI-modified PSCs. A higher R_{rec} matched with the data taken from former recombination investigations, resulting in less hysteresis behaviors and better device performance of PEI—CH₃NH₃PBI₃ PSCs.

TPC measurements were used to measure charge carrier extraction time of the PSCs. By applying a reverse bias, all photo-generated charge carriers would be swept out and the time scale could be detected. By filling the linear region of current decay on the TPC curve, charge carrier extraction times could be calculated. The TPC curves were generated under −0.9 V bias for both the pristine and PEI modified PSCs, where extraction lifetimes were estimated to be 90 nano-seconds for the PEI—CH₃NH₃PBI₃ PSC and 160 nano-seconds for the pristine PSC. The diminished extraction lifetime indicated a quicker and more efficient charge carrier process for the PEI—CH₃NH₃PBI₃ PSC. The PEI—CH₃NH₃PBI₃ PSC had a higher photo-induced charge density, in agreement with the J-V characterization results. Both the IS and TPC results indicated that the PEI—CH₃NH₃PBI₃ PSCs had better electronic properties as compared to the pristine PSCs.

The stability of pristine PSCs and PEI—CH₃NH₃PBI₃ PSCs were studied by testing device performance under a long period of time. All devices were kept in a glovebox in an N₂ atmosphere (with O₂ concentration lower than 100 ppm and the H₂O concentration lower than 0.1 ppm) at room temperature. Both the pristine PSCs and the PEI—CH₃NH₃PBI₃ PSCs suffered from a quick dropping off of the PCE during the first three days. The stability issue existed at the interface of the active layer and the electron transfer layer (ETL). FF was lost from 73.7% to 57.8% for the PEI—CH₃NH₃PBI₃ PSC and similar results were seen with the pristine PSC, which was indicative of an interface issue. However, the PEI—CH₃NH₃PBI₃ PSC had a better overall device stability when the results were normalized. Although performance decreased over time, it took 12 days for the PEI—CH₃NH₃PBI₃ PSC to reach half-life stability (50% decreasing of PCE), while it took only 6 days for the pristine PSC to reach half-life stability. From SEM images, the PEI—CH₃NH₃PBI₃ film possessed less pin-holes and grain boundaries, which were the main channels for the penetration of moisture and oxygen. These penetrations might cause degradation of the perovskite film, resulting in poor device stability. Therefore, PEI modified PSCs have better stability due to a better film quality of the active layer.

Other embodiments of the present invention utilize ionic salts as additives to the perovskite in a perovskite solar cell (PSCs) in order to address photocurrent hysteresis. The major origin of photocurrent hysteresis, ion migration, can be frozen through the interaction of ionic additives with the counter ions from the perovskite.

Ionic salts can be added into perovskite to “freeze” ion migration by electrostatic forces from counter ions. In such embodiments, virtually any perovskite (ABX₃) may be chosen, and virtually any ionic salt. In perovskite, disordered ions are mainly MA⁺ and X⁻, which generate migration and hysteresis issues. By introducing an ionic salt, counter anions interact with M+ (e.g., CH₃NH₃⁺) and counter cations give force to X⁻ (e.g., I—), such that ion migration can be suppressed. In some embodiments, the ionic salt is tetrabutylammonium trifluoromethanesulfonate (TATS), and the perovskite is CH₃NH₃PBI₃wherein the ammonium groups freeze movement of I⁻ while the sulfonate group suppresses migration of CH₃NH₃⁺. As a result, restricted photocurrent hysteresis is observed from PSCs fabricated with a CH₃NH₃PBI₃-TATS active layer.

In one embodiment of the present invention, in order to create a TATS modified perovskite thin film; the following steps are taken. First, a precursor solution utilizing either Pb²⁺ or Sn²⁺ bonded to a halide can be prepared. For example, Pb²⁺ bonded with I⁻ can be selected to prepare a precursor solution of PbI₂, PbI₂ is added into a solvent solution, such as for example, a combination of DMF and DMSO. Next, a solution utilizing either CH₃NH₃⁺ or NH₂CH═NH₂⁺. must be prepared. For example, methyl ammonium iodide (MAI) is selected to mix in CH₃NH₃⁺. These two solutions are created to make a perovskite precursor solution. These two solutions are combined in an equal molar ratio. The perovskite precursor solution can then be mixed with a TATS solution dissolved in a solvent solution, such as for example, DMF, at a concentration of about 5 mg mL⁻¹. When the TATS modified perovskite thin films are created, they are made in multiple concentrations of perovskite:TATS of 400:10, 400:20, and 400:30.

Once the TATS modified thin film has been created, it can be utilized to create a perovskite solar cell (PSC). In one embodiment of the present invention, in order to prepare the PSC, the following steps are taken. First, a material to create an anode electrode needs to be selected from the group consisting of indium tin oxide (ITO). Once selected, the anode electrode can be treated with UV-ozone for about 40 minutes under an ambient atmosphere. The next step is to select a material to create a hole extraction layer selected from the group consisting of nickel oxyhydroxide (NiOₓ) or poly(3,4-ethylenedioxythiophene) polystyrene sulfonate (PEDOT:PSS). Once selected, the material to create the hole extraction layer is spun cast on top of the anode electrode utilizing a hole extraction layer precursor solution to create about a 30 nm thick film layer. Once the hole extraction layer has be spun cast onto the anode electrode, it is thermally annealed for about 10 minutes at about 150° C., and then placed into a glovebox with an N₂ atmosphere.

The next step is to take the TATS modified perovskite thin film and deposit it on top of the hole extraction layer utilizing a one-step method using spin-coating. This step is used to create a light harvesting active layer. Then, an anti-solvent, such as toluene, is dripped for about 15-10 seconds at the conclusion of the spin-coating. A 300 nm TATS modified perovskite layer is then created after 10 minutes of thermal annealing at 100° C. The next step is to let the device cool down to room temperature and then a material is selected to create an electron extraction layer selected from the group consisting of phenyl-C61-butyric acid methyl ester (PC₆₁BM). Once selected, the material selected to create the electron extraction layer is spun cast onto the TATS modified thin film layer.

The final step is to select a material to create a cathode electrode selected from the group consisting of aluminum. Once selected, the material selected to create the cathode electrode is deposited by a shadow mask in a vacuum onto the electron extraction layer.

Top view scanning electron microscope (SEM) was performed to characterize the morphology of the perovskite thin films. Pristine CH₃NH₃PBI₃ layers had small grain size with a lot of grain boundaries. In comparison, CH₃NH₃PBI₃-TATS modified layers possessed smoother surfaces with larger grain sizes. A higher photocurrent and more efficient charge transport process can be expected from larger grain sizes, therefore resulting in better device performance for devices utilizing CH₃NH₃PBI₃-TATS active layers.

Solar cell J-V performance with CH₃NH₃PBI₃ active layers having different concentrations of TATS additive were studied. Compared with PSCs utilizing pristine CH₃NH₃PBI₃, an enhancement in short circuit current density (J_{SC}) from 400:10 and 400:20 (CH₃NH₃PBI₃:TATS) can be observed. The increased J_{SC} gives rise to higher PCE, where the best efficiency of 12.6% comes from a 400:10 device with a J_{SC} of 21.5 mA cm⁻². The enhanced photocurrent matches with former results from SEM images wherein TATs modified perovskite possesses larger grain size. EQE spectra of devices having different concentrations of TATS additive were also studied. With increasing concentration of TATS, relatively poor device performance was witnessed, especially for 400:30 devices. When there is a high concentration of TATS (400:30), only a part of the additive works as a freezing agent, while the excessive parts are just impurity, giving more defects to the perovskite active layer. Decreased J_{SC} was also witnessed with devices having a higher concentration of TATS. This date indicated that no obvious affect to the interface area or energy level was observed, only changes in photocurrent hysteresis can be expected. Therefore, the amount of TATS additive need to be tailored to not add defects to the active layer.

Photocurrent hysteresis behavior is characterized by testing device performance under revers/forward scan directions. Device hysteresis behavior can be clearly described through the difference or reverse/forward scan J-V curves and corresponding hysteresis indexes. For pristine PSCs hysteresis comes from the loss in photocurrent and FF. This behavior can be described as a “de-trapping” process, where large forward bias can suppress build-in potential and fill traps by electron injection. When real photocurrent is generated there will be less trap and the photocurrent and FF will be higher. Reverse bias can enhance inner electrical fields, giving force for ion migration while forward bias will suppress that process. Therefore, critical J-V hysteresis behaviors can be observed from reverse scans and forward scans of pristine PSCs. However, with TATS enhanced PSCs, those differences become smaller. By calculating the hysteresis index, perovskite incorporated with the proper concentration of additive (400:10) give hysteresis indexes of 0.06, which is smaller than pristine perovskite devices. A conclusion can therefore be drawn that J-V hysteresis can be reduced after introducing TATS ionic additives into CH₃NH₃PBI₃ perovskite devices.

To investigate electrical properties of perovskite active layers, impedance spectrum (IS) was utilized to measure the charge transport resistance (R_{CT}) and recombination resistance (R_{rec}). The IS of PSCs fabricated with or without TATS ionic additives were studied. From equivalent circuits, R_{CT} and R_{rec} were calculated as resistance between two intersection points of a Nyquist plot and the Z′ axis. Pristine PSCs has an R_{CT} of 90Ω while TATS additive modified PSCs had a smaller R_{CT} of 90Ω, suggesting a better charge transport process being achieved in TATS additive modified PSCs. This matches with the higher photocurrent in the J-V characterizations, giving further evidence to better device performance. The R_{rec} of pristine PSCs was calculated as 4750Ω while TATS additive modified PSCs possessed a R_{rec} of 5550Ω, indicating less recombination behaviors in the latter. Transient photocurrent (TPC) measurements were used to measure charge carrier extraction times of PSCs. By fitting linear regions of current decay on the TPC curves, charge carrier extraction times can be calculated. TPC curves were takes under −0.9 V bias and the extraction lifetime was estimated to be 125 nano-seconds for the TATS additive modified PSCS and 150 nano-seconds for the pristine PSCs. The diminished extraction lifetime indicates quicker and more efficient charge carrier extraction process. Both the IS and TPC results indicate that TATS ionic additive modified PSCs have better electronic properties, suggesting promising enhancements when utilizing TATS additives.

Considering the foregoing, it should be appreciated that the present invention significantly advances the art by providing modified perovskites and enhanced perovskite solar cell that are structurally and functionally improved in several ways. While embodiments of the invention have been disclosed in detail herein, it should be appreciated that the invention is not limited thereto or thereby inasmuch as variations on the invention herein will be readily appreciated by those of ordinary skill in the art. The scope of the invention shall be appreciated from the claims that follow.

### EXAMPLES

### Experiment 1

PEO with different molecular weight (M_{w}) (M_{w}=500, 1000, and 4500 Da) were purchased from Scientific Polymer Inc.; [6,6]-Phenyl-C61-butyric acid methyl ester (PC₆₁BM) (99.5%) was purchased from Solenne BV; and lead iodide (PbI₂, 99.999%, beads), anhydrous N,N-dimethylformamide (DMF), dimethyl sulfoxide (DMSO), ethanol (99.5%), and chlorobenzene (99.8%) were purchased from Sigma-Aldrich. All chemicals were used as received without further purification.

Both pristine CH₃NH₃PBI₃ and the PEO—CH₃NH₃PBI₃ thin films were prepared by a two-step method. PbI₂ precursor solution was prepared by adding PbI₂ (400 mg, 0.87 mmol/mL) into a solution of DMF and DMSO (1 mL 97.5:2.5 v/v %). The PbI₂ precursor solution was mixed with the respective PEO solution adding PEO (10.0 mg) with different M_{w}. The M_{w} of the PEO materials were 500 Da, 1000 Da, and 4500 Da. Since PEO with M_{w}>4500 Da is difficult to dissolve in DMF, PEO with M_{w}>4500 Da was excluded from the study. For studies measuring the influence of PEO concentration, PEO with M_{w}=4500 Da was selected, and the PEO concentrations were tuned from 1%, to 3%, 5%, and 10% (w% to PbI₂), respectively, while maintaining the PbI₂ concentration at 400 mg/mL (0.87 mmol/mL). Afterward, either the PbI₂ layer or the PbI₂ layer mixed with the PEO precursor was firstly deposited on the substrates by spin-casting (3500 RPM, at 75° C.). Then, the methyl ammonium iodide (MAI) layer was deposited on the top of either the PbI₂ layer or the PbI₂ layer mixed with the PEO precursor by spin-casting (3500 RPM) from MAI precursor solution (35 mg/ml, 0.22 mmol/mL in ethanol), followed with thermal annealing at 100° C. for two hours to create the final perovskite thin films.

The previously mentioned MAI layer was prepared by reacting hydroiodic acid (114 mmol, 15 mL, 57 wt. %) and methylamine (140 mmol, 70 mL, 2.0 M in methanol) at 0° C. with stirring under a nitrogen atmosphere for two hours. The resultant solution was evaporated to give a white precipitate, and then the precipitate was washed with diethyl ether several times until the diethyl ether ran completely colorless. Afterward, the white precipitate was dried under vacuum for 48 hours and used without further purification.

To create the PSCs, the ITO glass was cleaned by detergent, deionized water, acetone, and isopropanol sequentially. Then, the ITO-glasses were dried in an oven at 100° C. overnight. The pre-cleaned ITO substrates were then treated with UV-ozone for 40 minutes under an ambient atmosphere. Then, an about 40 nm thick film of NiOₓ was spin-casted on the top of the ITO substrates from an NiOₓ precursor solution. Either a pristine CH3NH3PbI3 thin film or a PEO—CH₃NH₃PBI₃ thin film was then deposited on the top of the NiOₓ layer via a top-step method. Afterward, a 40 nm-thick PC₆₁BM layer was spun-cast onto the perovskite layer from a 20 mg/mL chlorobenzene solution. Finally, a 120 nm-thick aluminum (Al) film was deposited through a shadow mask in a vacuum with a base line of about 2×10⁻⁶ mbar atmosphere. The device areas were measured to be 0.16 cm².

### Experiment 2

Lead iodide (PbI₂, 99.999%), tetrabutylammonium trifluoromethanesulfonate (TATS), anhydrous N,N-dimethylformamide (DMF, 99.8%), anhydrous ethanol (>99.5%), anhydrous toluene (99.8%), and anhydrous chlorobenzene (99.8%) were purchased from Sigma-Aldrich. Methylammonium iodide (CH₃NH₃I) was purchased from Greatcell Solar. PEDOT-PSS was purchased from Heraeus. [6,6]-phenyl-C61-butyric acid methylester (PC₆₁BM, 99.5%) was purchased from Solenne BV.

The perovskite precursor solution was prepared by taking 1.2M PbI₂ and CH₃NH₃I and dissolving them in DMF:DMSO (4:1 volume ratio), where PbI₂ and CH3NH3I are equal in molar ratio. TATS was dissolved in DMF with a concentration of 5 mg mL⁻¹. All these precursor solutions were magnetically stirred at 70° C. overnight. Before device fabrication, additive solutions were added into the perovskite precursor solution by volume ratio and magnetically stirred for one hour. Specifically, CH₃NH₃PBI₃:TATS was made with three concentrations of 400:10, 400:20, and 400:30.

To fabricate the devices, precleaned ITO substrates were treated with UV-Ozone for 40 minutes and then a 30 nm PEDOT:PSS layer was spun-coated on top of the ITO substrates at 3500 RPM for 30 seconds, followed by 10 minutes of thermal annealing at 150° C. Then, all substrates were transferred into a glovebox with an N₂ atmosphere. A one-step method was performed to fabricate the perovskite active layer by spin-coating the perovskite precursor solution at 4000 RPM for 30 seconds. Then, 200 μL of anti-solvent toluene was dripped at 15-10 seconds to the end of the spin-coating. A 300 nm perovskite layer was formed after 10 minutes of thermal annealing at 100° C. After the device was cooled down to room temperature, 50 nm PC₆₁BM layer was spun-coated on top of the perovskite layer at 1500 RPM for 30 seconds, by using 20 mg mL⁻¹ PC₆₁BM chlorobenzene solution. Finally, 100 nm Al was thermally deposited by using shadow mask at a high vacuum (1×10⁻⁵ mbar).

### Experiment 3

Lead iodide (PbI₂, 99.999%), anhydrous N,N-dimethylformamide (DMF, 99.8%), anhydrous ethanol (>99.5%), anhydrous toluene (99.8%), and anhydrous chlorobenzene (99.8%) were purchased from Sigma-Aldrich, Linear polyethylenimine (PEI, MW 2500) was purchased from Polyscience. Methylammonium iodide (CH₃NH₃I) was purchased from Greatcell Solar. PEDOT:PSS was purchased from Heraeus. [6,6]-phenyl-C61-butyric acid methylester (PC₆₁BM, 99.5%) was purchased from Solenne BV.

The perovskite precursor solution was prepared by taking 1.2M PbI₂ and CH₃NH₃I and dissolving them in DMF:DMSO (4:1 volume ratio), where PbI₂ and CH₃NH₃I are equal in molar ratio. PEI was then dissolved in ethanol with a concentration of 2.5 mg mL⁻¹. All these precursor solutions were then magnetically stirred at 70° C. overnight. Before device fabrication, additive solutions were added into the perovskite precursor solutions by volume ratio and magnetically stirred for one hour. Specifically, CH₃NH₃PBI₃:PEI was made with four concentrations of 400:5, 400:10, 400:20, and 400:40.

To fabricate the devices, precleaned ITO substrates were treated with UV-Ozone for 40 minutes and then a 40 nm PEDOT:PSS layer was spun-coated on top of the ITO substrate at 3500 RPM for 30 seconds, followed by 10 minutes of thermal annealing at 150° C. Then, all substrates were transferred into a glovebox with N₂ atmosphere. A one-step method was performed to fabricate the perovskite active layer by spin-coating the precursor solution at 4000 RPM for 30 seconds. Then, 200 μL of anti-solvent toluene was dripped at 15-10 seconds to the end of the spin-coating. A 300 nm perovskite layer was formed after 10 minutes of thermal annealing at 100° C. After the device was cooled down to room temperature, a 50 nm PC₆₁BM layer was spun-coated on top of the perovskite layer at 1500 RPM for 30 seconds by using 20 mg mL⁻¹ PC₆₁BM chlorobenzene solution. Finally, 100 nm Al was thermally deposited by using shadow mask at a high vacuum (1×10⁻⁵ mbar).

What is claimed is:

1. A modified perovskite comprising a polymer and a perovskite wherein the polymer is co-crystallized with the perovskite.

2. The modified perovskite of claim 1 wherein the polymer is selected from the group consisting of poly(ethylene oxide) (PEO) and polyethylenimine (PEI).

3. The modified perovskite of claim 2 wherein the perovskite has the formula ABX₃ wherein A is selected from the group consisting of CH₃NH₃⁺ or NH₂CH═NH₂⁺, B is selected from the group consisting of Pb²⁺ or Sn²⁺, and X is a halide.

4. The modified perovskite of claim 3 wherein X is selected from the group consisting of Cl⁻, Br⁻, or I⁻.

5. The modified perovskite of claim 4 wherein A is CH₃NH₃⁺, B is Pb²⁺, and X is I⁻.

6. The modified perovskite of claim 3 wherein the polymer anchors the CH₃NH₃⁺ at the A-site of the perovskite and the I⁻ at the X-site of the perovskite through the formation of hydrogen bonds between the polymer and the perovskite.

7. A perovskite solar cell comprising a light harvesting active layer comprising a modified perovskite comprising a polymer and a perovskite wherein the polymer is co-crystallized with the perovskite.

8. The perovskite solar cell of claim 7 wherein the polymer is selected from the group consisting of poly(ethylene oxide) (PEO) and polyethylenimine (PEI).

9. The perovskite solar cell of claim 8 wherein the perovskite the formula ABX₃ wherein A is selected from the group consisting of CH₃NH₃⁺ or NH₂CH═NH₂⁺, B is selected from the group consisting of Pb²⁺ or Sn²⁺, and X is a halide.

10. The perovskite solar cell of claim 9 wherein X is selected from the group consisting of Cl⁻, Br⁻, or I⁻.

11. The perovskite solar cell of claim 10 wherein A is CH₃NH₃⁺, B is Pb²⁺, and X is I⁻.

12. The perovskite solar cell of claim 7 further comprising an anode electrode selected from the group consisting of indium tin oxide (ITO).

13. The perovskite solar cell of claim 10 further comprising a hole extraction layer selected from the group consisting of nickel oxyhydroxide (NiOₓ) or poly(3,4-ethylenedioxythiophene) polystyrene sulfonate (PEDOT:PSS).

14. The perovskite solar cell of claim 11 further comprising an electron extraction layer selected from the group consisting of phenyl-C61-butyric acid methyl ester (PC₆₁BM).

15. The perovskite solar cell of claim 12 further comprising a cathode electrode selected from the group consisting of aluminum.

16. A modified perovskite film comprising:
a. an ionic salt; and
b. a perovskite having the formula ABX₃, wherein counter anions of the ionic salt interact with A and counter cations interact with X, such that ion migration is suppressed.

17. The modified perovskite of claim 16 wherein the ionic salt is selected from the group consisting of tetrabutylammonium trifluoromethanesulfonate (TATS).

18. The modified perovskite of claim 17 wherein A is selected from the group consisting of CH₃NH₃⁺ or NH₂CH═NH₂⁺, B is selected from the group consisting of Pb²⁺ or Sn²⁺, and X is a halide

19. The modified perovskite of claim 18 wherein X is selected from the group consisting of Cl⁻, Br⁻, or I⁻.

20. The modified perovskite of claim 19 wherein A is CH₃NH₃⁺, B is Pb²⁺, and X is I⁻.
